(19) United States
(12) Patent Application Publication
(10) Pub. No.: US 2026/0013142 A1
(43) Pub. Date: Jan. 8, 2026

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Hui-Lin Wang, Taipei City (TW); Shun-Yu Huang, Kaohsiung City (TW); Ya-Wei Shih, Tainan City (TW); Che-Wei Chang, Taichung City (TW); Chen-Yi Weng, New Taipei City (TW); Kun-Chen Ho, Tainan City (TW)

(73) Assignee: UNITED MICROELECTRONICS CORP., Hsin-Chu City (TW)

(21) Appl. No.: 18/792,520

(22) Filed: Aug. 1, 2024

(30) Foreign Application Priority Data
Jul. 2, 2024 (TW) 113124624

(51) Int. Cl. H10B 61/00; G01R 33/09; H10N 50/01; H10N 50/20

(52) U.S. Cl. CPC H10B 61/22; G01R 33/098; H10N 50/01; H10N 50/20

(57) ABSTRACT

A method for fabricating a magnetoresistive random access memory (MRAM) device includes the steps of first forming a spin orbit torque (SOT) layer on a substrate, forming a magnetic tunneling junction (MTJ) on the SOT layer, and then forming a first cap layer on the MTJ and the SOT layer. Preferably, a first angle included by a top surface of the SOT layer and a top surface of the first cap layer includes an acute angle.

### BACKGROUND OF THE INVENTION

### 1. Field of the Invention

The invention relates to a semiconductor device and method for fabricating the same, and more particularly to a magnetoresistive random access memory (MRAM) and method for fabricating the same.

### 2. Description of the Prior Art

Magnetoresistance (MR) effect has been known as a kind of effect caused by altering the resistance of a material through variation of outside magnetic field. The physical definition of such effect is defined as a variation in resistance obtained by dividing a difference in resistance under no magnetic interference by the original resistance. Currently, MR effect has been successfully utilized in production of hard disks thereby having important commercial values. Moreover, the characterization of utilizing GMR materials to generate different resistance under different magnetized states could also be used to fabricate MRAM devices, which typically has the advantage of keeping stored data even when the device is not connected to an electrical source.

The aforementioned MR effect has also been used in magnetic field sensor areas including but not limited to for example electronic compass components used in global positioning system (GPS) of cellular phones for providing information regarding moving location to users. Currently, various magnetic field sensor technologies such as anisotropic magnetoresistance (AMR) sensors, GMR sensors, magnetic tunneling junction (MTJ) sensors have been widely developed in the market. Nevertheless, most of these products still pose numerous shortcomings such as high chip area, high cost, high power consumption, limited sensibility, and easily affected by temperature variation and how to come up with an improved device to resolve these issues has become an important task in this field.

### SUMMARY OF THE INVENTION

According to an embodiment of the present invention, a method for fabricating a magnetoresistive random access memory (MRAM) device includes the steps of first forming a spin orbit torque (SOT) layer on a substrate, forming a magnetic tunneling junction (MTJ) on the SOT layer, and then forming a first cap layer on the MTJ and the SOT layer. Preferably, a first angle included by a top surface of the SOT layer and a top surface of the first cap layer includes an acute angle.

According to another aspect of the present invention, a magnetoresistive random access memory (MRAM) device includes a spin orbit torque (SOT) layer on a substrate, a magnetic tunneling junction (MTJ) on the SOT layer, and a first cap layer on the MTJ and the SOT layer. Preferably, a first angle included by a top surface of the SOT layer and a top surface of the first cap layer includes an acute angle.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-9 illustrate a method for fabricating a MRAM device according to an embodiment of the present invention.

### DETAILED DESCRIPTION

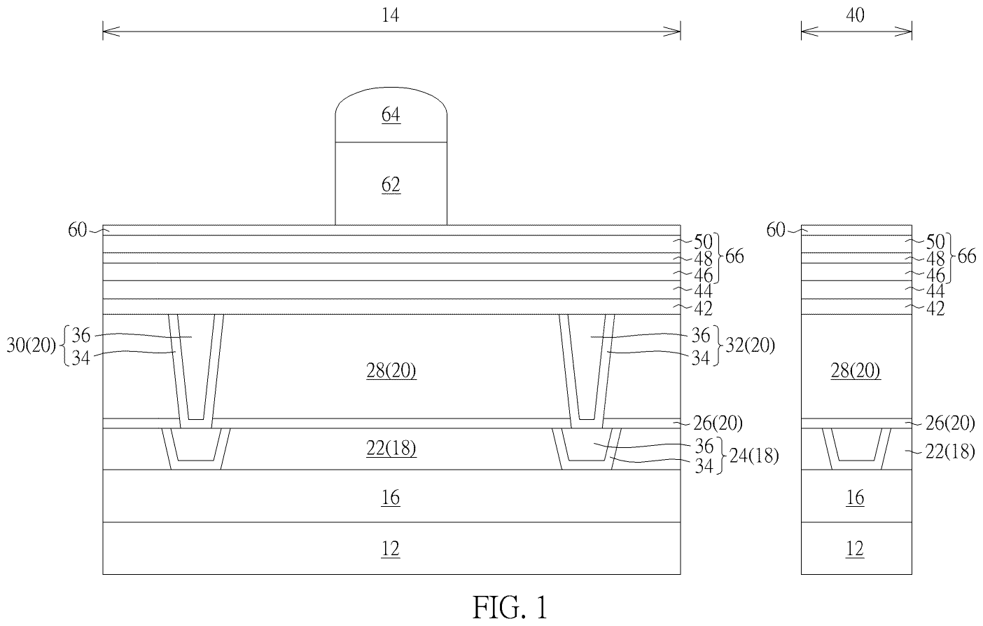

Referring to FIGS. 1-9, FIGS. 1-9 illustrate a method for fabricating a semiconductor device, or more specifically a MRAM device according to an embodiment of the present invention. As shown in FIG. 1, a substrate 12 made of semiconductor material is first provided, in which the semiconductor material could be selected from the group consisting of silicon (Si), germanium (Ge), Si—Ge compounds, silicon carbide (SiC), and gallium arsenide (GaAs), and a MRAM region 14 and a logic region 40 are defined on the substrate 12.

Active devices such as metal-oxide semiconductor (MOS) transistors, passive devices, conductive layers, and interlayer dielectric (ILD) layer 16 could also be formed on top of the substrate 12. More specifically, planar MOS transistors or non-planar (such as FinFETs) MOS transistors could be formed on the substrate 12, in which the MOS transistors could include transistor elements such as gate structures (for example metal gates) and source/drain region, spacer, epitaxial layer, and contact etch stop layer (CESL). The ILD layer 16 could be formed on the substrate 12 to cover the MOS transistors, and a plurality of contact plugs could be formed in the ILD layer 16 to electrically connect to the gate structure and/or source/drain region of MOS transistors. Since the fabrication of planar or non-planar transistors and ILD layer is well known to those skilled in the art, the details of which are not explained herein for the sake of brevity.

Next, metal interconnect structures 18, 20 are sequentially formed on the ILD layer 16 to electrically connect the aforementioned contact plugs, in which the metal interconnect structure 18 includes an inter-metal dielectric (IMD) layer 22 and metal interconnections 24 embedded in the IMD layer 22, and the metal interconnect structure 20 includes a stop layer 26, an IMD layer 28, and metal interconnections 30, 32 embedded in the stop layer 26 and the IMD layer 28. It should be noted that in contrast to metal interconnections 24, 30, 32 are disposed in the IMD layers 24, 28 on the MRAM region 14, only metal interconnection 24 is embedded in the IMD layer 22 while no metal interconnection is disposed in the IMD layer 28 on the logic region 40 at this stage.

In this embodiment, each of the metal interconnections 24 from the metal interconnect structure 18 preferably includes a trench conductor and each of the metal interconnections 30, 32 from the metal interconnect structure 20 includes a via conductor. Preferably, each of the metal interconnections 24, 30, 32 from the metal interconnect structures 18, 20 could be embedded within the IMD layers 22, 28 and/or stop layer 26 according to a single damascene process or dual damascene process. For instance, each of the metal interconnections 24, 30, 32 could further include a barrier layer 34 and a metal layer 36, in which the barrier layer 34 could be selected from the group consisting of titanium (Ti), titanium nitride (TiN), tantalum (Ta), and tantalum nitride (TaN) and the metal layer 36 could be selected from the group consisting of tungsten (W), copper (Cu), aluminum (Al), titanium aluminide (TiAl), and cobalt tungsten phosphide (CoWP). Since single damascene process and dual damascene process are well known to those skilled in the art, the details of which are not explained herein for the sake of brevity. In this embodiment, the metal layers 36 in the metal interconnections 24 are preferably made of copper, the metal layers 36 in the metal interconnections 30, 32 are preferably made of tungsten, the IMD layers 22, 28 are preferably made of silicon oxide or ultra low-k (ULK) dielectric layer, and the stop layers 26 is preferably made of nitrogen doped carbide (NDC), silicon nitride, silicon carbon nitride (SiCN), or combination thereof.

Next, a selective bottom electrode 42, a spin orbit torque (SOT) layer 44, a MTJ stack 66, a cap layer 60, and a patterned mask or top electrode (TE) 62 are formed on the metal interconnect structure 20. In this embodiment, the formation of the MTJ stack 66 could be accomplished by sequentially depositing a free layer 46, a barrier layer 48, a reference layer (not shown), a spacer (not shown), and a pinned layer 50 on the SOT layer 44. Preferably, the free layer 46 could be made of ferromagnetic material including but not limited to for example iron, cobalt, nickel, or alloys thereof such as cobalt-iron-boron (CoFeB), in which the magnetized direction of the free layer 46 could be altered freely depending on the influence of outside magnetic field. The barrier layer 48 could be made of insulating material including but not limited to for example oxides such as aluminum oxide (AlOx) or magnesium oxide (MgO).

The reference layer is disposed between the barrier layer 48 and the spacer, in which the reference layer could be made of ferromagnetic material including but not limited to for example iron, cobalt, nickel, or alloys thereof such as cobalt-iron-boron (CoFeB). The spacer could be a non-magnetic layer made of non-magnetic material including but not limited to for example ruthenium (Ru), iridium (Ir), rhodium (Rh), or combination thereof.

The pinned layer 50 could be made of antiferromagnetic (AFM) material including but not limited to for example ferromanganese (FeMn), platinum manganese (PtMn), iridium manganese (IrMn), nickel oxide (NiO), or combination thereof, in which the pinned layer 50 is formed to fix or limit the direction of magnetic moment of adjacent layers. Specifically, the pinned layer 50 further includes a bottom synthetic antiferromagnetic (SAF) layer, a coupling layer, and a top SAF layer, in which the bottom SAF layer and the top SAF layer could include same or different materials while both layers could include ferromagnetic material such as cobalt (Co), nickel (Ni), platinum (Pt), palladium (Pd), or combination thereof. The coupling layer may also include materials to provide mechanical and/or crystalline structural support for the bottom SAF layer and the top SAF layer. Preferably, the coupling layer includes material that aides in this coupling including but not limited to ruthenium (Ru), tantalum (Ta), gadolinium (Gd), platinum (Pt), hafnium (Hf), or combination thereof.

Moreover, the selective bottom electrode 42 could include conductive material such as but not limited to for example Ta, TaN, Pt, Cu, Au, Al, or combination thereof, the SOT layer 44 is serving as a channel for the MRAM device as the SOT layer 44 could include metals such as tantalum (Ta), tungsten (W), platinum (Pt), or hafnium (Hf) and/or topological insulator such as bismuth selenide (BixSe₁₋ₓ). The cap layer 60 preferably includes metal such as Ru, and the TE 62 preferably includes conductive or dielectric material such as tantalum (Ta), tantalum nitride (TaN), titanium (Ti), titanium nitride (TiN), platinum (Pt), copper (Cu), gold (Au), aluminum (Al), or combination thereof.

In this embodiment, the formation of the patterned TE 62 could be accomplished by first forming a dielectric layer 64 made of silicon oxide on an un-patterned TE 62 and then using a patterned mask (not shown) such as patterned resist as mask to remove part of the dielectric layer 64 and part of the TE 62 through reactive ion etching (RIE) process for forming a patterned dielectric layer 64 and a patterned TE 62. The dielectric layer 64 made of silicon oxide could be selectively removed thereafter.

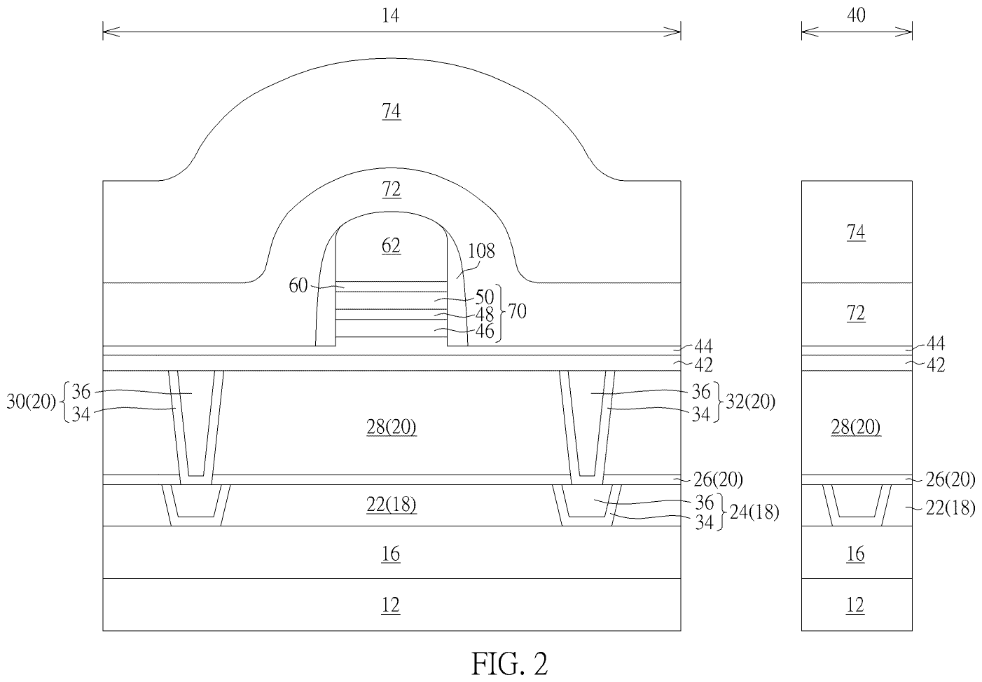

Next, as shown in FIG. 2, the patterned dielectric layer 64 or the patterned TE 62 could be used as a mask to remove part of the cap layer 60, part of the MTJ stack 66, and even part of the SOT layer 44 for forming a MTJ 70, and then a first cap layer 72 is formed on the MTJ 70 and a first oxide layer 74 is formed on the first cap layer 72. Preferably, the MTJ stack 66 on the logic region 40 is completely removed at this stage and during the aforementioned patterning process, parameters of the etching process are adjusted so that the top surface of the TE 62 directly on top of the MTJ 70 would form a curved surface. Since the top surface of the TE 62 has a curved surface, both the top surface of the first cap layer 72 and the top surface of the first oxide layer 74 directly on top of the TE 62 also has a curved surface.

It should be noted that after the MTJ stack 66 is patterned to form the MTJ 70, each sidewall of the MTJ 70 preferably includes an inclined surface connected to the curved top surface of the TE 62 and the first cap layer 72 formed afterwards is disposed conformally on the MTJ 70 along the curvy profiles of the TE 62 and MTJ 70. Moreover, it should also be noted that when the MTJ stack 66 is patterned by the aforementioned etching process to form the MTJ 70, part of metal ions could be sputtered upward to form doped regions 108 on sidewalls of the MTJ 70. Preferably, the doped regions 108 could include materials such as TiN from the TE 62 or metals such as iron (Fe), cobalt (Co), nickel (Ni), or alloy thereof from the MTJ 70.

In this embodiment, the first cap layer 72 is preferably made of silicon nitride while the first oxide layer 74 is made of silicon oxide or tetraethoxysilane (TEOS). It should be noted that when the patterned TE 62 is used to pattern the MTJ stack 66 for forming the MTJ 70, part of the SOT layer 44 could be removed at the same time so that the top surface of the remaining SOT layer 44 adjacent to two sides of the MTJ 70 is slightly lower than the top surface of the SOT layer 44 directly under the MTJ 70. According to an embodiment of the present invention, if none of the SOT layer 44 were removed during the formation of the MTJ 70, the top surface of the SOT layer 44 adjacent to two sides of the MTJ 70 would be even with the top surface of the SOT layer 44 directly under the MTJ 70. Moreover, the first cap layer 72 and the first oxide layer 74 formed at this stage are preferably disposed on the MRAM region 14 and the logic region 40 at the same time.

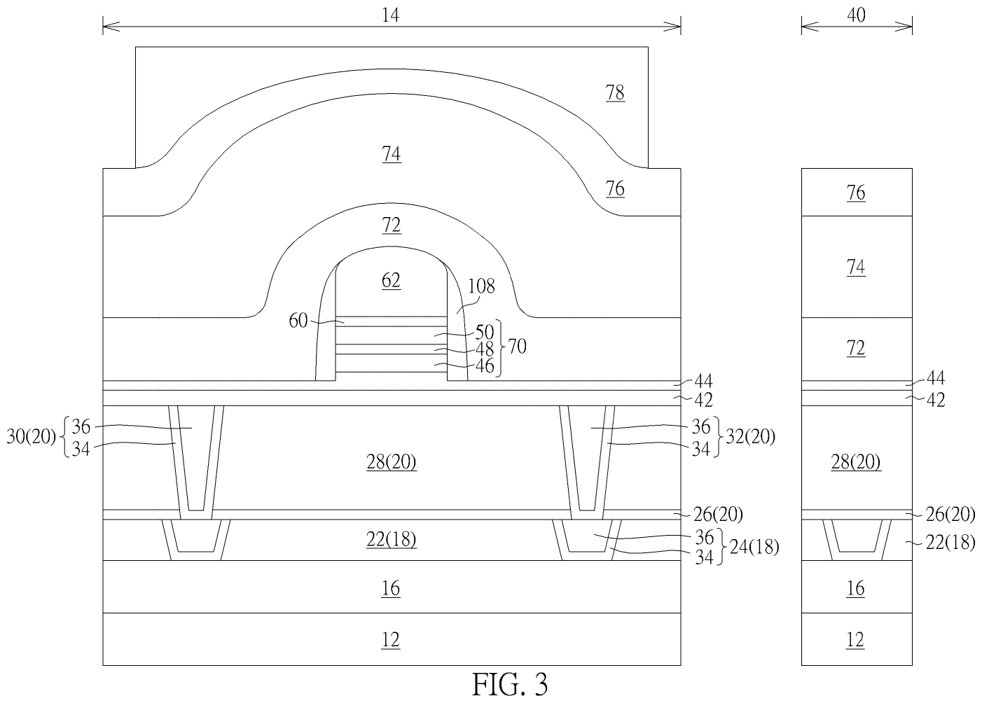

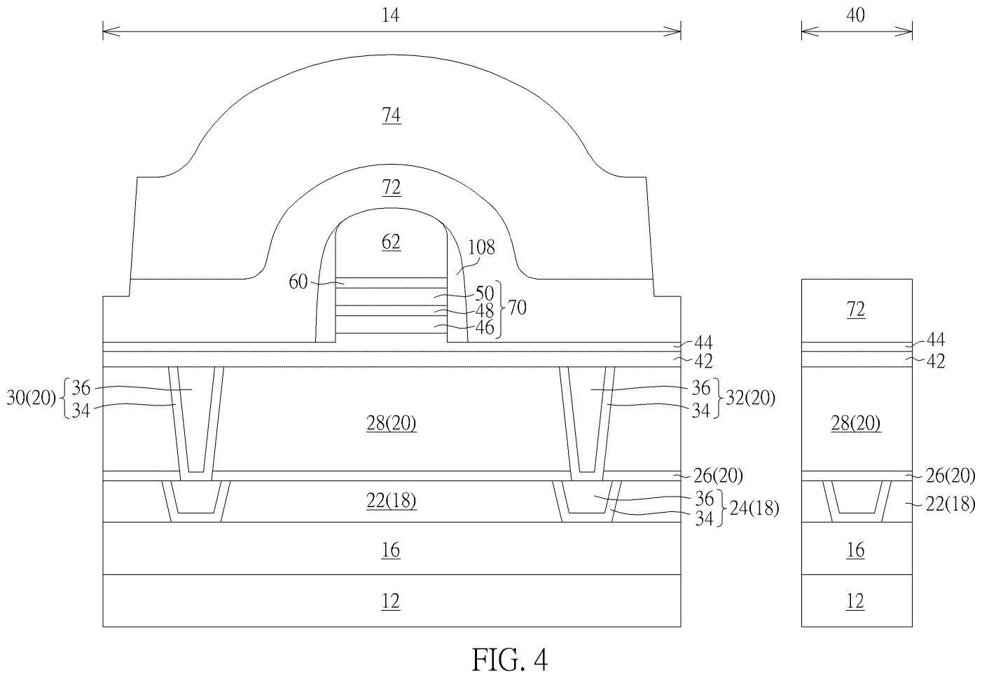

Next, as shown in FIGS. 3-4, a bottom anti-reflective coating (BARC) 76 is formed on the first oxide layer 74, and then an etching process such as another RIE process is conducted by using a patterned mask 78 such as a patterned resist as mask to remove part of the BARC 76, part of the first oxide layer 74, and part of the first cap layer 72 on the MRAM region 14 and all of the BARC 76 and first oxide layer 74 on the logic region 40 for exposing the surface of the first cap layer 72 underneath. Preferably, the remaining first oxide layer 74 is only disposed on the MRAM region 14 while the first cap layer 72 underneath is still disposed on the MRAM region 14 and the logic region 40. The BARC 76 is then removed to expose the first oxide layer 74 on the MRAM region 14. It should be noted that after part of the first oxide layer 74 is removed by the aforementioned etching process, part of the first cap layer 72 could be removed so that sidewalls of the first oxide layer 74 and the first cap layer 72 are aligned.

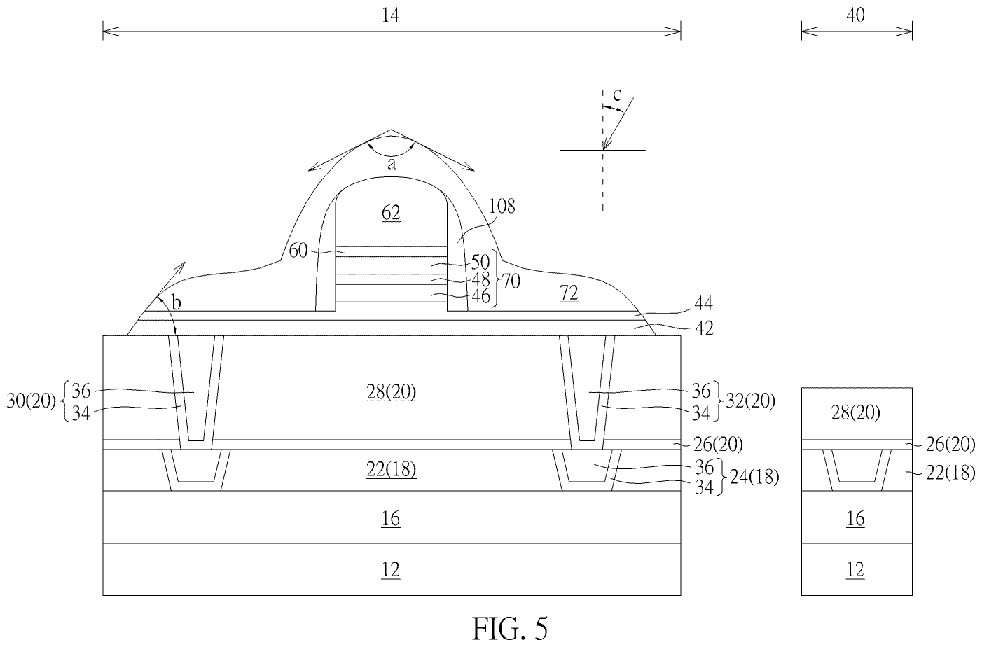

Next, as shown in FIG. 5, an etching process such as an ion beam etching (IBE) process is conducted with or without patterned mask at an angle c to remove all of the first oxide layer 74, part of the first cap layer 72, part of the SOT layer 44, and part of the bottom electrode 42 on the MRAM region 14 and all of the first cap layer 72, all of the SOT layer 44, all of the bottom electrode 42, and all part of the IMD layer 28 on the logic region 40 so that the first cap layer 72, SOT layer 44, and bottom electrode 42 on the MRAM region 14 are shaped to form inclined sidewalls aligned with each other. The top surface of the remaining IMD layer 28 on the logic region 40 on the other hand is slightly lower than the top surface of the IMD layer 28 on the MRAM region 14. In this embodiment, the angle c is preferably less than 50 degrees or most preferably between 10-30 degrees.

It should be noted the IBE process conducted at this stage not only removes the first oxide layer 74, but also shapes the first cap layer 72 so that the first cap layer 72 originally having a substantially even thickness is partially trimmed to have greater thickness directly on top of the MTJ 70 and surface of the SOT layer 44 adjacent to two sides of the MTJ 70 and smaller thickness on sidewalls of the MTJ 70. After being trimmed, the first cap layer 72 directly on top of the MTJ 70 and the first cap layer 72 adjacent to two sides of the MTJ 70 preferably have two different angles, in which a vertex or an angle included by top surface of the first cap layer 72 directly on top of the MTJ 70 includes an angle a, the angle a being an obtuse angle, and the angle a is greater than 90 degrees or most preferably between 100-160 degrees. Another angle b could also be formed between the top surface of the SOT layer 44 adjacent to two sides of the MTJ 70 and the inclined top surface of the first cap layer 72, the top surface of the bottom electrode 42 and the top surface of the first cap layer 72, or the top surface of the IMD layer 28 and the top surface of the first cap layer 72, in which the angle b is an acute angle, and the angle b is less than 70 degrees or most preferably between 30-60 degrees.

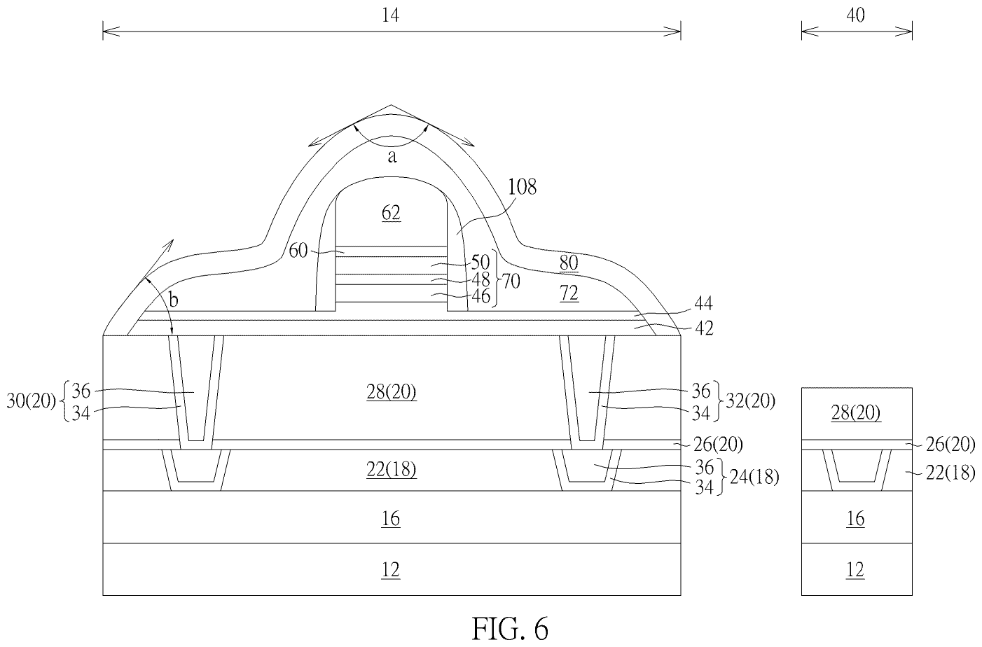

Next, as shown in FIG. 6, a second cap layer 80 is formed on the surface of the first cap layer 72 on the MRAM region 14, and an etching back process could be conducted by using a patterned mask (not shown) to remove part of the second cap layer 80 on the MRAM region 14 and all of the second cap layer 80 on the logic region 40 for exposing the surface of the IMD layer 28. In this embodiment, the first cap layer 72 and the second cap layer 80 are preferably made of same material such as silicon nitride (SiN), in which the first cap layer 72 is a silicon rich layer as the silicon concentration of the first cap layer 72 is preferably greater than the silicon concentration of the second cap layer 80. Since the second cap layer 80 is conformally disposed on the surface of the first cap layer 72, the second cap layer 80 directly on top of the MTJ 70 and the second cap layer 80 adjacent to two sides of the MTJ 70 also have two different angles.

Preferably, the vertex of the second cap layer 80 directly on top of the MTJ 70 includes an angle a, the angle a being an obtuse angle, and the angle a is greater than 90 degrees or most preferably between 100-160 degrees. Moreover, another angle b could be formed between the top surface of the SOT layer 44 adjacent to two sides of the MTJ 70 and the top surface of the second cap layer 80, the top surface of the bottom electrode 42 and the top surface of the second cap layer 80, or the top surface of the IMD layer 28 and the top surface of the second cap layer 80, in which the angle b is an acute angle, and the angle b is less than 70 degrees or most preferably between 30-60 degrees.

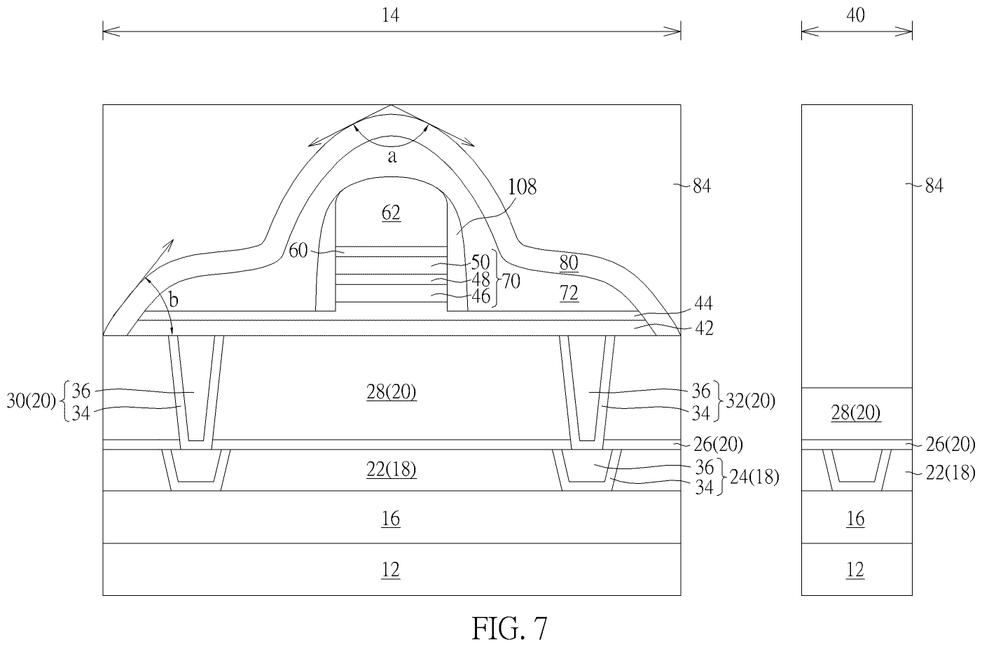

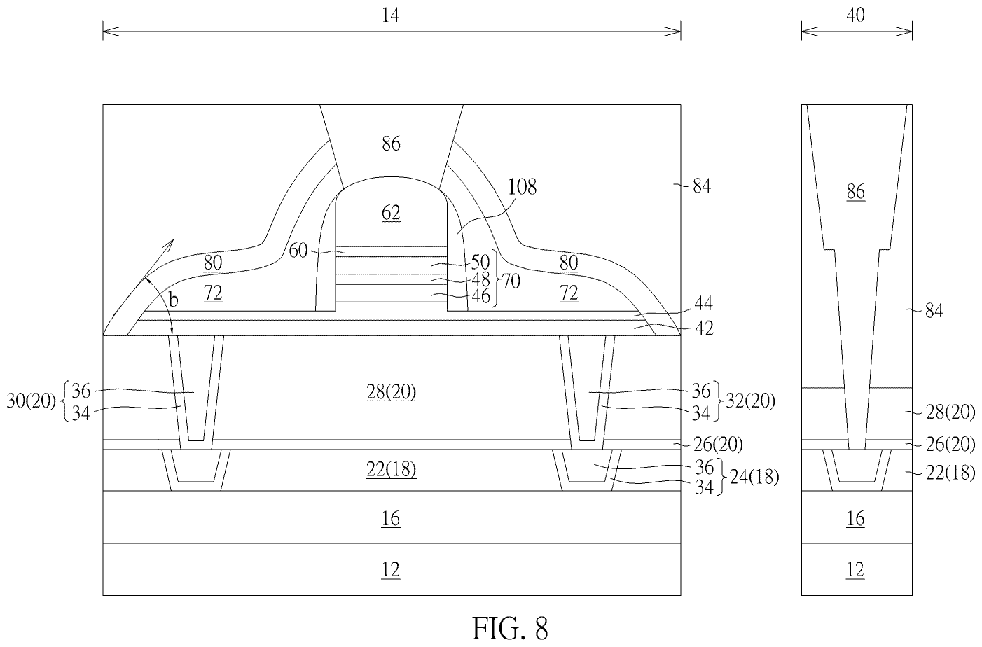

Referring to FIGS. 7-8, FIGS. 7-8 illustrate a method for fabricating a MRAM device following FIG. 6 under different perspective according to different embodiments of the present invention. As shown in FIGS. 7-8, a second oxide layer 84 is formed on the MRAM region 14 and logic region 40, a planarizing process such as chemical mechanical polishing (CMP) is conducted to remove part of the second oxide layer 84, and then a pattern transfer process is conducted by using a patterned mask (not shown) to remove part of the second oxide layer 84 and part of the first cap layer 72 on the MRAM region 14 and part of the IMD layer 84, part of the IMD layer 28, and part of the stop layer 26 on the logic region 40 to form contact holes (not shown) exposing the TE 62 and the metal interconnection 24 underneath and conductive materials are deposited into the contact holes afterwards. For instance, a barrier layer selected from the group consisting of titanium (Ti), titanium nitride (TiN), tantalum (Ta), and tantalum nitride (TaN) and metal layer selected from the group consisting of tungsten (W), copper (Cu), aluminum (Al), titanium aluminide (TiAl), and cobalt tungsten phosphide (CoWP) could be deposited into the contact holes, and a planarizing process such as CMP could be conducted to remove part of the conductive materials including the aforementioned barrier layer and metal layer to form metal interconnections 86 in the contact holes electrically connecting the TE 62 and the metal interconnection 24. Since FIG. 7 is taken along the cross-section adjacent to the metal interconnection 86 while FIG. 8 is taken along the cross-section directly above the metal interconnection 86, the feature of metal interconnection 86 directly connecting the TE 62 is only shown in FIG. 8

In this embodiment, the first oxide layer 74 and the second oxide layer 84 preferably include different dielectric constant or more specifically the dielectric constant of the second oxide layer 84 is less than the dielectric constant of the first oxide layer 74. Preferably, the dielectric constant of the first oxide layer 74 is between 3.2-4.2, the dielectric constant of the second oxide layer 84 is between 2.4-2.8 or most preferably 2.8, and the ratio of the first oxide layer 74 dielectric constant to the second oxide layer 84 dielectric constant is between 1.2-1.6. In this embodiment, the first oxide layer 74 preferably includes TEOS or silicon oxide while the second oxide layer 84 includes an ultra low-k (ULK) dielectric layer including but not limited to for example porous material or silicon oxycarbide (SiOC) or carbon doped silicon oxide (SiOCH).

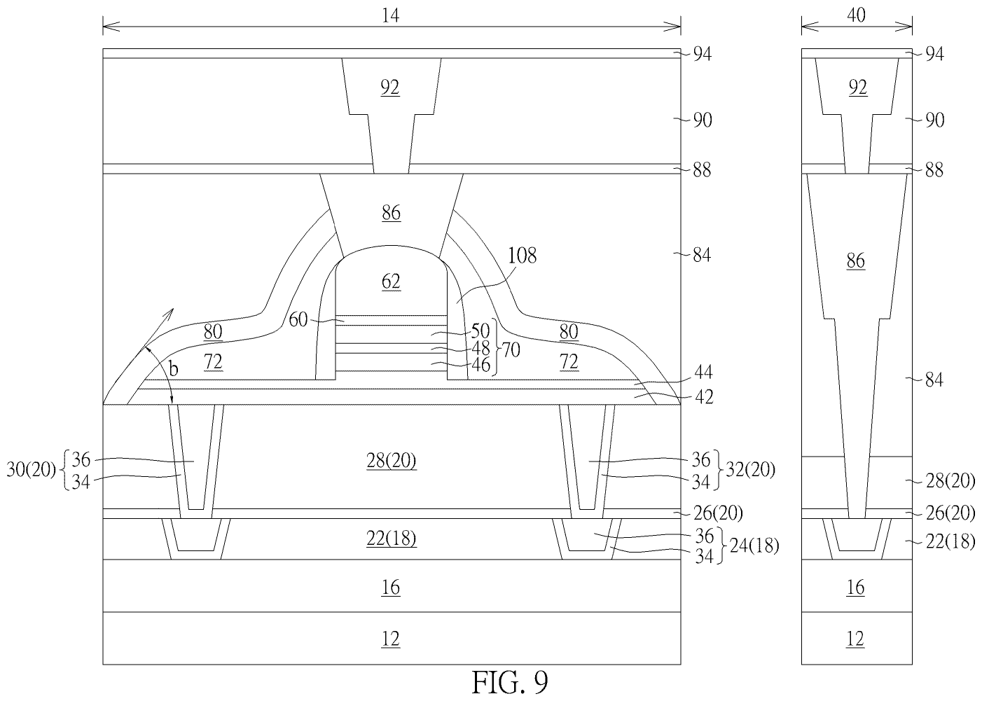

Next, as shown in FIG. 9, a stop layer 88 is formed on the metal interconnections 86, an IMD layer 90 is formed on the stop layer 88 of the MRAM region 14 and logic region 40, and a pattern transfer process is conducted by using a patterned mask (not shown) to remove part of the IMD layer 90 and part of the stop layer 88 for forming contact holes (not shown) exposing the metal interconnections 86 and conductive materials are deposited into the contact hole afterwards. For instance, a barrier layer selected from the group consisting of titanium (Ti), titanium nitride (TiN), tantalum (Ta), and tantalum nitride (TaN) and metal layer selected from the group consisting of tungsten (W), copper (Cu), aluminum (Al), titanium aluminide (TiAl), and cobalt tungsten phosphide (CoWP) could be deposited into the contact holes, and a planarizing process such as CMP could be conducted to remove part of the conductive materials including the aforementioned barrier layer and metal layer to form metal interconnections 92 in the contact holes electrically connecting the metal interconnections 86. Next, a stop layer 94 is formed on the metal interconnection 92. In this embodiment, the IMD layer 90 preferably includes an ultra low-k (ULK) dielectric layer including but not limited to for example porous material or silicon oxycarbide (SiOC) or carbon doped silicon oxide (SiOCH).

Referring again to FIG. 7, FIG. 7 further illustrates a structural view of a MRAM device according to an embodiment of the present invention. As shown in FIG. 7, the MRAM device includes a SOT layer 44 disposed on the substrate 12, a MTJ 70 disposed on the SOT layer 44, a first cap layer 72 disposed on the MTJ 70 and the SOT layer 44, and a second cap layer 80 disposed on the first cap layer 72. Preferably, the vertex of the first cap layer 72 or second cap layer 80 directly on top of the MTJ 70 includes an angle a, the angle a being an obtuse angle, and the angle a is greater than 90 degrees or most preferably between 100-160 degrees. Moreover, another angle b could be formed between the top surface of the SOT layer 44 adjacent to two sides of the MTJ 70 and the top surface of the first cap layer 72, the top surface of the bottom electrode 42 and the top surface of the first cap layer 72, or the top surface of the IMD layer 28 and the top surface of the first cap layer 72, in which the angle b is an acute angle, and the angle b is less than 70 degrees or most preferably between 30-60 degrees.

Overall, the present invention discloses a SOT MRAM device and fabrication method thereof, which first forms a SOT layer 44 and MTJ 70 on the substrate, forms a first cap layer 72 on the MTJ and the SOT layer, removes part of the first cap layer through etching process and at the same time shapes the profile of the first cap layer so that the thickness of the first cap layer 72 directly on top of the MTJ 70 and on surface of the SOT layer 44 adjacent to two sides of the MTJ 70 is slightly greater than the thickness of the first cap layer 72 on sidewalls of the MTJ 70. In the meantime, an acute angle b preferably less than 70 degrees is formed between the top surface of the SOT layer and the top surface of the first cap layer while an obtuse angle a preferably greater than 90 degrees is formed at the apex of the first cap layer directly above the MTJ. By using the above approach for adjusting profiles of the first cap layer 72 and the second cap layer 80, it would be desirable to fill more IMD layer adjacent to the MTJ in the later process thereby improving insulation capability for the device.

Those skilled in the art will readily observe that numerous modifications and alterations of the device and method may be made while retaining the teachings of the invention. Accordingly, the above disclosure should be construed as limited only by the metes and bounds of the appended claims

What is claimed is:

1. A method for fabricating a magnetoresistive random access memory (MRAM) device, comprising:
forming a spin orbit torque (SOT) layer on a substrate;
forming a magnetic tunneling junction (MTJ) on the SOT layer; and
forming a first cap layer on the MTJ and the SOT layer, wherein a first angle included by a top surface of the SOT layer and a top surface of the first cap layer comprises an acute angle.

2. The method of claim 1, wherein the substrate comprises a MRAM region and a logic region, the method further comprising:
forming an inter-metal dielectric (IMD) layer on the substrate;
forming a first metal interconnection and a second metal interconnection in the IMD layer;
forming the SOT layer on the first metal interconnection and the second metal interconnection;
forming a top electrode (TE) on the MTJ;
forming the first cap layer on the MTJ and the SOT layer;
forming a first oxide layer on the first cap layer on the MRAM region and the logic region;
performing a first etching process to remove the first oxide layer on the logic region;
performing a second etching process to remove the first oxide layer on the MRAM region and shape the first cap layer;
forming a second cap layer on the first cap layer;
performing a third etching process to remove the second cap layer on the logic region; and
forming a second oxide layer on the second cap layer.

3. The method of claim 2, wherein a top surface of the TE comprises a curve.

4. The method of claim 2, further comprising performing the second etching process to form the first angle.

5. The method of claim 2, further comprising performing the second etching process to form a second angle included by the first cap layer directly on top of the MTJ.

6. The method of claim 5, wherein the second angle is greater than 90 degrees.

7. The method of claim 2, wherein a third angle included by a top surface of the SOT layer and a top surface of the second cap layer is less than 70 degrees.

8. The method of claim 1, wherein the first angle is less than 70 degrees.

9. A magnetoresistive random access memory (MRAM) device, comprising:
a spin orbit torque (SOT) layer on a substrate;
a magnetic tunneling junction (MTJ) on the SOT layer; and
a first cap layer on the MTJ and the SOT layer, wherein a first angle included by a top surface of the SOT layer and a top surface of the first cap layer comprises an acute angle.

10. The MRAM device of claim 9, further comprising:
an inter-metal dielectric (IMD) layer on the substrate;
a first metal interconnection and a second metal interconnection in the IMD layer;
the SOT layer on the first metal interconnection and the second metal interconnection;
a top electrode (TE) on the MTJ;
the first cap layer on the MTJ and the SOT layer;
a second cap layer on the first cap layer; and
an oxide layer on the second cap layer.

11. The MRAM device of claim 10, wherein a top surface of the TE comprises a curve.

12. The MRAM device of claim 10, wherein a second angle included by the first cap layer directly on top of the MTJ is greater than 90 degrees.

13. The MRAM device of claim 10, wherein a third angle included by a top surface of the SOT layer and a top surface of the second cap layer is less than 70 degrees.

14. The MRAM device of claim 10, wherein a fourth angle included by the second cap layer directly on top of the MTJ is greater than 90 degrees.

15. The MRAM device of claim 9, wherein the first angle is less than 70 degrees.
